(19) United States
(12) Patent Application Publication
(10) Pub. No.: US 2009/0299919 A1
(43) Pub. Date: Dec. 3, 2009

(54) CALCULATING UTILITY CONSUMPTION OF AT LEAST ONE UNIT OF A BUILDING

(76) Inventor: Christopher J. Frutkin, Cincinnati, OH (US)

Correspondence Address: WOOD, HERRON & EVANS, LLP, 2700 CAREW TOWER, 441 VINE STREET, CINCINNATI, OH, 45202, US

(21) Appl. No.: 12/472,904

(22) Filed: May 27, 2009

Related U.S. Application Data
(60) Provisional application No. 61/056,154, filed on May 27, 2008.

(51) Int. Cl. G06Q 10/00; G01R 21/00

(52) U.S. Cl. 705/412; 702/61

(57) ABSTRACT

A method, apparatus and program product provide for calculating the utility consumption of at least one unit of a building having a plurality of units. The method includes determining a square footage of the at least one unit, sensing a temperature of the at least one unit over a predetermined period of time, and calculating utility consumption for the at least one unit based at least in part on the determined square footage of the at least one unit and the sensed temperature of the at least one unit.

### CROSS-REFERENCE TO RELATED APPLICATIONS

This application is related to and claims the filing benefit of U.S. Patent Application Ser. No. 61/056,154 to Christopher J. Frutkin entitled “METHOD OF CALCULATING UTILITY CONSUMPTION” and filed on May 27, 2008, which application is incorporated by reference in its entirety herein.

### FIELD OF THE INVENTION

This application relates to determining the utility consumption of a building of the type that includes a plurality of units, and more particularly to allocating the share of at least one unit of the utility consumption in an equitable manner.

### BACKGROUND OF THE INVENTION

Multi-unit buildings often have central heating, air conditioning, domestic water heating (e.g., hot water heaters), electric and/or water systems such that managers of the buildings (e.g., landlords) can pass on the cost of the utilities to tenants in their rent. Utility providers, however, often provide those utilities and measure them through a central meter. As such, sub-metering is often difficult, if not impossible. For example, sub-metering may require additional lines put in, additional hardware and meters installed as well as additional resources devoted to measuring and maintaining such. As such, it is generally difficult to determine utility consumption of a particular unit that is provided utilities from a central heating, air conditioning, domestic water heating, electric and/or water system.

Moreover, it is often difficult to determine the utility consumption of a particular unit that has a different footprint (e.g., arrangement, layout, square footage, internal partitioning) than other units of a building. For example, in many buildings there are often a variety of units. The variety of units may include units that have different arrangements, layouts, square footages and/or internal partitionings. Thus, it is more expensive to adjust the temperature of a first unit with a large square footage to a particular temperature as opposed to adjusting the temperature of a second unit with a smaller square footage to that particular temperature.

Conventionally, managers of buildings rent spaces and include the costs of utility consumption in the rents thereof. However, this fails to take into account the actual utility consumption of units. For example, a first unit may be consistently kept at a high temperature while a second unit may be consistently kept at a lower temperature, often reducing the utility consumption of that second unit during the winter but increasing the utility consumption of that second unit during the summer when the two units have approximately the same square footage. Moreover, splitting the costs of centralized systems evenly among tenants further fails to take into account the square footage of units. For example, a first unit and second unit may be kept at the same temperature, but it may take more utility consumption to keep the first unit at the temperature when the first unit is larger than the second unit.

Furthermore, tenants often have little or no incentive to reduce their utility consumption, conserve energy and/or otherwise increase the efficiencies of their respective unit(s). For example, utility consumption may account for from about 20% to about 30% of an expense budget for a building. Tenants, however may waste approximately 15%-40% of their utility consumption. Thus, managers of buildings are often forced to increase their budgets to account for that waste while suffering a decrease in property value and return on investment.

Consequently, there is a need to address the deficiencies of the prior art in such a manner that accounts for allocating the utility consumption of a building of the type that includes a plurality of units in a more equitable manner.

### SUMMARY OF THE INVENTION

Thus, embodiments of the invention provide a method, apparatus and program product to address the deficiencies of the prior art. In some embodiments of the invention, a method of calculating the utility consumption of at least one unit of a building is provided. In particular, embodiments of the invention determine average temperatures both inside and outside a building during several predetermined periods of times. The utility consumption of the building during those predetermined period of times is also determined. These average temperatures and utility consumptions related thereto are used to establish a temperature baseline that indicates the utility consumption required to adjust at least a portion of building from the average outside temperature to the average inside temperature. In particular, best fit interpolations of the determined average temperatures and utility consumptions related thereto may be used to calculate the temperature baseline. For example, about ten measurements of the average inside and outside temperatures during about ten predetermined periods of time may be determined, along with respective utility consumptions during those respective predetermined periods of time. In some embodiments, the temperature baseline may be stored in a table wherein the rows thereof may indicate average outside temperatures and the columns thereof may indicate average inside temperatures.

When the temperature baseline has been established, the average inside temperature for a unit may be sensed during a predetermined period of time. Additionally, the average outside temperature of the building may also be sensed for the same period of time. Thus, a column corresponding to the sensed average inside temperature may be cross-referenced to a row corresponding to the sensed average outside temperature to determine the utility consumption for the unit required to adjust the unit from the average outside temperature to the average inside temperature. From this determined utility consumption, the unit's share of the total utility consumption, as well as the unit's share of the total utility consumption costs, may be determined. In this manner, the utility consumption for at least one unit of a building may be determined.

Particular embodiments of the invention provide for a method of calculating utility consumption for at least one unit of a building having a plurality of units. The method comprises determining a square footage of the at least one unit, sensing a temperature of the at least one unit over a predetermined period of time, and calculating the utility consumption for the at least one unit based at least in part on the determined square footage of the at least one unit and the sensed temperature of the at least one unit.

These and other advantages will be apparent in light of the following figures and detailed description.

### BRIEF DESCRIPTION OF THE DRAWINGS

The accompanying drawings, which are incorporated in and constitute a part of this specification, illustrate embodiments of the invention and, together with a general description of the invention given above and the detailed description of the embodiments given below, serve to explain the principles of the invention.

FIG. 1 is a diagrammatic illustration of at least a portion of a building having a plurality of units consistent with embodiments of the invention;

FIG. 2 is a diagrammatic illustration of a system to calculate the utility consumption of at least one unit of the building of FIG. 1;

FIG. 3 is a diagrammatic illustration of a plurality of components of a data store that may be configured on a computing system of FIG. 2;

FIG. 4 is a diagrammatic illustration of a plurality of components of a utility calculation and management application that may be configured on the computing system of FIG. 2;

FIG. 5 is a flowchart illustrating a plurality of blocks to set up a calculation of utility consumption of at least one unit of the building of FIG. 1;

FIG. 6 is a flowchart illustrating a plurality of blocks to calculate the utility consumption of at least one unit of the building of FIG. 1;

FIG. 7 is a flowchart illustrating a plurality of blocks to discard anomalous temperature readings by a temperature sensor consistent with embodiments of the invention;

FIG. 8 is a display representation of a graph that illustrates a relationship between the average utility consumption associated with a building and the average outside temperature associated with that building consistent with embodiments of the invention;

FIG. 9 is a display representation that diagrammatically illustrates at least a portion of the data store of FIG. 2 and FIG. 3; and

FIG. 10 is a display representation of at least a portion of a calculation and information screen to input information related to the utility consumption of at least one unit of the building of FIG. 1 and indicate a calculation of the utility consumption associated therewith.

It should be understood that the appended drawings are not necessarily to scale, presenting a somewhat simplified representation of various features illustrative of the basic principles of embodiments of the invention. The specific design features of embodiments of the invention as disclosed herein, including, for example, specific dimensions, orientations, locations, and shapes of various illustrated components, as well as specific sequences of operations (e.g., including concurrent and/or sequential operations), will be determined in part by the particular intended application and use environment. Certain features of the illustrated embodiments may have been enlarged or distorted relative to others to facilitate visualization and clear understanding.

### DETAILED DESCRIPTION

In some embodiments of the invention, a method of calculating the utility consumption of at least one unit of a building is provided. In particular, embodiments of the invention determine average temperatures both inside and outside a building during several predetermined periods of times. The utility consumption of the building during those predetermined period of times is also determined. These average temperatures and utility consumptions related thereto are used to establish a temperature baseline that indicates the utility consumption required to adjust at least a portion of building from the average outside temperature to the average inside temperature. In particular, best fit interpolations of the determined average temperatures and utility consumptions related thereto may be used to calculate the temperature baseline. For example, about ten measurements of the average inside and outside temperatures during about ten predetermined periods of time may be determined, along with respective utility consumptions during those respective predetermined periods of time. In some embodiments, the temperature baseline may be stored in a table wherein the rows thereof may indicate average outside temperatures and the columns thereof may indicate average inside temperatures.

When the temperature baseline has been established, the average inside temperature for a unit may be sensed during a predetermined period of time. Additionally, the average outside temperature of the building may also be sensed for the same period of time. Thus, a column corresponding to the sensed average inside temperature may be cross-referenced to a row corresponding to the sensed average outside temperature to determine the utility consumption for the unit required to adjust the unit from the average outside temperature to the average inside temperature. From this determined utility consumption, the unit's share of the total utility consumption, as well as the unit's share of the total utility consumption costs, may be determined. In this manner, the utility consumption for at least one unit of a building may be determined.

### Hardware and Software Environment

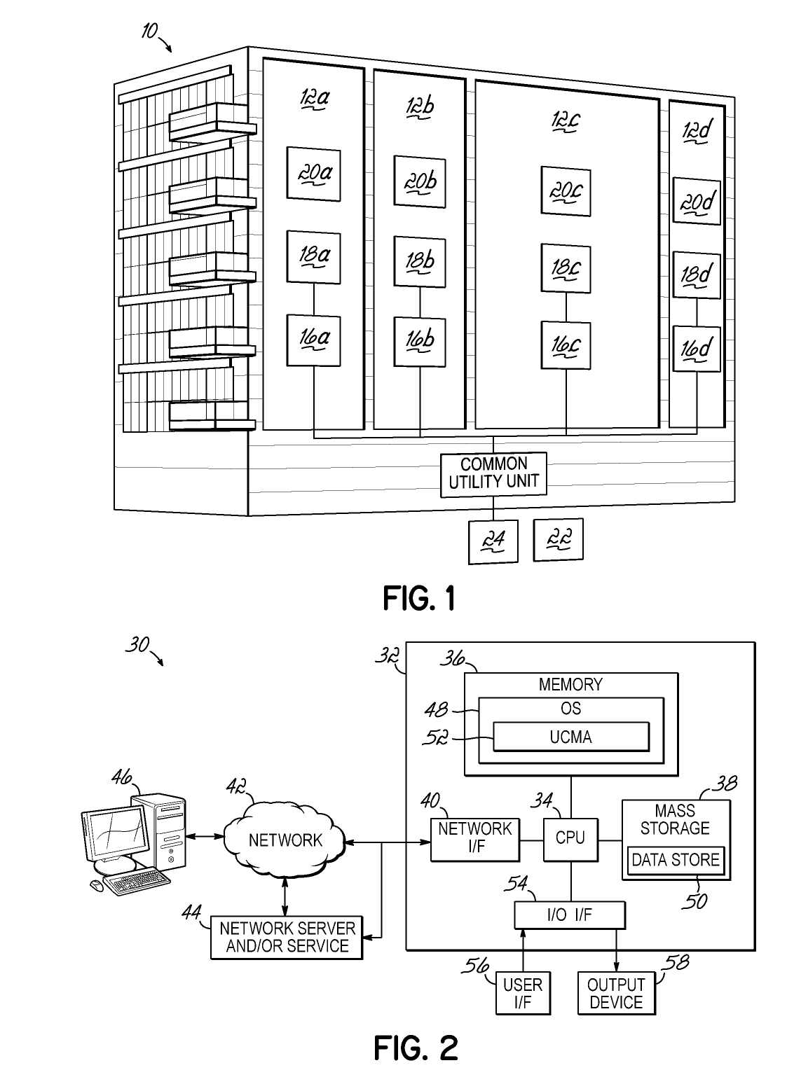

Turning to the drawings, wherein like numbers denote like parts throughout the several views, FIG. 1 generally illustrates at least a portion of a building 10 that includes a plurality of units 12a-d. In some embodiments the building 10 includes a central utility consumption element 14 (illustrated as, and hereinafter, “common utility unit” 14, which may be a boiler, furnace, air conditioning unit, etc.) that may provide a medium (e.g., a heated or cooled medium, such as water or air) to at least one heating and/or cooling unit 16a-d associated with a respective unit 12a-d. Each unit 16a-d, in turn, is associated with and controlled by a respective thermostat 18a-d. As such, the interior temperature of each unit 12a-d may be individually controlled by a tenant associated therewith (e.g., an individual, a business entity).

In some embodiments, at least one interior temperature sensor 20 is disposed in at least a portion of the units 12 (e.g., one or more) of the building 10. In specific embodiments, at least one interior temperature sensor 20a-d is disposed in respective each unit 12a-d of the building 10. Each interior temperature sensor 20a-d is configured to determine a temperature over a period of time. For example, at least one interior temperature sensor 20a-d may be configured to determine the average temperature of its respective unit 12a-d over about a six-hour period, about a twelve-hour period, about a day, about a week, about two weeks, about a month and/or about a year. In specific embodiments, each interior temperature sensor 20a-d is a ceiling mounted projection temperature sensor. Similarly, at least one exterior temperature sensor 22 is disposed outside of the building 10 and/or the units 12a-d to determine a temperature associated with the outside of the building 10 over a period of time. For example, at least one exterior temperature sensor 22 may be configured to determine the average temperature associated with the outside of the building 10 over about a six-hour period, about a twelve-hour period, about a day, about a week, about two weeks, about a month and/or about a year.

In some embodiments, each of the sensors 20 and/or 22 is low power temperature sensor configured to be take a plurality of temperature measurements over the period of time and average them, then provide that average to at least one sensor reader (not shown) and/or at least one computing system (not shown in FIG. 1). Specifically, each sensor 20, 22 may communicate with a sensor reader through a wireless communication protocol, such as a radio frequency and/or Bluetooth®. Alternatively, each sensor 20, 22 may be configured to communicate with a sensor reader through a wired connection. Further alternatively, each sensor 20, 22 may be configured to communicate with the at least one computing system and simply provide the plurality of temperature measurements over the period of time to the at least one computing system for that at least one computing system to average. Furthermore, the sensors 20, 22 may include a combination of sensors in which a first portion (e.g., one or more) are configured to communicate with the at least one sensor reader and/or a second portion are configured to communicate with the at least one computing system. In some embodiments, each sensor 20, 22 is a tamper resistant sensor. In some embodiments, each sensor 20, 22 includes a battery monitoring circuit to trigger a notification (e.g., an alert, alarm and/or a web-based notification) to indicate that service is needed.

In some embodiments, a meter 24 may track the utility consumption of the building 10, and in particular the utility consumption of the common utility unit 14. The manager of the building 10 (e.g., a landlord) may then be charged by a utility provider based upon the utility consumption of the building 10.

FIG. 2 generally illustrates at least a portion of a system 30 for calculating the utility consumption of at least one of the units 12 of the building 10 consistent with the invention. In some embodiments, the system 30 includes at least one data processing apparatus 32. Apparatus 32, in specific embodiments, may be a computer, computer system, computing device, server, disk array, or programmable device such as a multi-user computer, a single-user computer, a handheld device, a networked device (including a computer in a cluster configuration), a mobile phone, a video game console (or other gaming system), etc. Apparatus 32 may be referred to as “computing apparatus,” but will be referred to herein as “computing system.”

The computing system 32 includes at least one central processing unit (“CPU”) 34 coupled to a memory 36. Each CPU 34 is typically implemented in hardware using circuit logic disposed on one or more physical integrated circuit devices or chips. Each CPU 34 is typically implemented in hardware using circuit logic disposed in one or more physical integrated circuit devices, or chips. Each CPU 34 may be one or more microprocessors, micro-controllers, field programmable gate arrays, or ASICs, while memory 36 may include random access memory (RAM), dynamic random access memory (DRAM), static random access memory (SRAM), flash memory, and/or another digital storage medium, and also typically implemented using circuit logic disposed on one or more physical integrated circuit devices, or chips. As such, memory 36 may be considered to include memory storage physically located elsewhere in the computing system 32, e.g., any cache memory in the at least one CPU 34, as well as any storage capacity used as a virtual memory, e.g., as stored on a mass storage device 38, a computer, or another controller coupled to computer through at least one network interface 40 (illustrated as, and hereinafter, “network I/F” 40) by way of at least one network 42. It will be appreciated that the at least one network 42 may include at least one private communications network (e.g., such as an intranet) and/or at least one public communications network (e.g., such as the Internet).

As illustrated in FIG. 2, the computing system 32 may be communicably coupled with at least one network server and/or service 44 (hereinafter, “service” 44) by way of the network 42 and/or directly. In specific embodiments, the computing system 32 is in communication with at least one computing system of the respective service 44, which may be an Internet service provider. As such, the computing system 32 may be configured to provide, to a user of the computing system 32 and/or a client 46 (and more specifically a network browser and/or computing system of the client 46), information associated with the utility consumption of at least one unit 12 of a building 10. The utility consumption information may be provided in a display representation, such as an application graphical user interface (“GUI”) provided by way of the output device 58. Alternatively, the display representation may include a web page provided by way of the network 42 and/or the service 44.

The computing system 32 may be under the control of an operating system 48 and execute or otherwise rely upon various computer software applications, sequences of operations, components, programs, files, objects, modules, etc., consistent with embodiments of the invention. In particular, the computing system 32 may be configured with a data store 50 as well as a utility calculation and management application 52 (illustrated as, and hereinafter, “UCMA” 52).

The computing system 32 may also include peripheral devices connected to the computer through an input/output device interface 54 (illustrated as, and hereinafter, “I/O I/F” 54). In particular, the computing system 32 may receive data from a user of the computing system 32 through at least one user interface 56 (including, for example, a keyboard, mouse, a microphone, and/or other user interface) and/or output data to the user through at least one output device 58 (including, for example, a display, speakers, a printer, and/or another output device). Moreover, in some embodiments, the I/O I/F 54 communicates with a device that is operative as a user interface 56 and output device 58 in combination, such as a touch screen display (not shown).

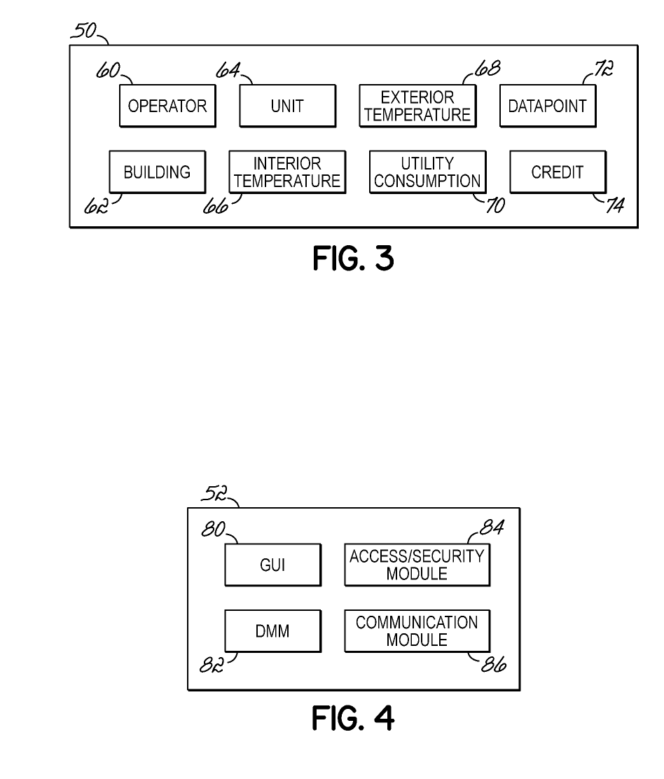

The data store 50 may be a database configured to store information associated with the building 10, units 12, sensors 20, 22, system 30, service 44, and/or client 46, among other information. As such, the data store 50 may in turn include a plurality of data stores, which may include tables, fields and/or arrays. FIG. 3 is a diagrammatic illustration of the principal components of one embodiment of the data store 50 consistent with embodiments of the invention. Specifically, the data store 50 may include an operator information table 60 to store information associated with the a user and/or a client 46, including registration information (e.g., their name, e-mail, address, phone number, fax number), logon information and/or other operator information (e.g., individual or business information). Similarly, the data store 50 may include a building table 62 and a unit table 64 to store information associated with a building 10 and/or units 12 thereof, respectively. For example, the building table 62 may include information associated with the location of a building, its name and/or a description. The unit table 64, in turn, may include information associated with units 12 of a building 10. For example, the unit table 64 may include information associated with the number of units 12 of a building 10, general information about each unit 12 of a building 10 (e.g., address information, contact information, billing information), the square footage of each unit 12, the number of heating and/or cooling units 16 of each unit 12 and/or other unit 12 information.

The data store 50 may be further configured with an interior temperature table 66 and an exterior temperature table 68 to store information associated with temperatures of units 12 and temperatures of the exterior of a building 10, respectively. Moreover, the data store 50 may include a utility consumption table 70 to store information associated with the utility consumption of a building 10 and/or a unit 12 thereof.

In some embodiments the data store 50 includes a data point table 72 to store data points associated with a relationship between the utility consumption required to adjust an average temperature of a building 10 (e.g., the average temperature of all units 12 of the building 10) from an average outside temperature to an average inside temperature. In specific embodiments, the data points may include measured data points (e.g., the utility consumption required at an average outside temperature to attain a specific average inside temperature of the building 12, or vice versa) as well as data points interpolated therefrom (e.g., the expected utility consumption required at an average outside temperature to attain a specific average inside temperature of the building 12, or vice versa). Finally, the data store 50 may include a credit table 74 to store information associated with at least one credit to a building 10 and, or unit 12 thereof.

In some embodiments the UCMA 52 is configured to calculate the utility consumption of a plurality of at least one unit 12 of a building 10 and provide that information to an operator (e.g., a user of the computing system 32 and/or a client 46). As such, the UCMA 52 may be configured with a plurality of components consistent with embodiments of the invention. For example, the UCMA 52 may include a GUI module 70 to provide a display representation of a user interface for the operator to interact with the UCMA 52, as well as to provide a display representation of information associated with the utility consumption of at least one unit 12 of a building 10.

In some embodiments, the UCMA 52 also includes a data management module 82 (illustrated as, and hereinafter, “DMM” 82) that may be used to interact with the data store 50. For example, and in specific embodiments where the data store 50 is a database, the DMM 82 is configured to execute an operation on the database, such, as a write, read and/or query consistent with embodiments of the invention. For example, the operator may interact with an interface, such as a web-page, to register. In turn, the interaction may be converted into a SQL statement by the DMM 82 to store information entered by the operator in the database. Also for example, the operator may interact with the interface to enter information or request information about utility consumption. In turn, the interaction may be converted into a SQL statement by the DMM 82 to perform at least one action on at least one table and/or field thereof of the database. In some embodiments, the DMM 82 may further optimize queries, generate execution plans, store execution plans create and/or analyze statistics based on queries, and/or otherwise include a database engine (not shown) consistent with embodiments of the invention.

In addition to the GUI 80 and DMM 82, the UCMA 52 may include an access and security module configured to control the access to the UCMA 52. For example, access to the UCMA 52 (e.g., an interface provided thereby and/or information provided therefrom) may require that a user name, password and/or personal identification number (“PIN”) be entered and verified. The UCMA 52 may further include a communication module 86 to communicate with the network 24, service 44, and/or client 46.

Those skilled in the art will appreciate that the environments illustrated in FIGS. 1-4 are not intended to limit embodiments of the present disclosure. In particular, while FIG.>1 illustrates a building that includes four units (12a, 12b, 12c and 12d), one having ordinary skill in the art will appreciate that the building 10 may include more or fewer units 12. Similarly, one having ordinary skill in the art will appreciate that when there are more or fewer units 12 there may be more or fewer heaters 16, thermostats 18, and/or interior temperature sensors 20, respectively. Moreover, and as illustrated in FIG. 1, units 12a-b are approximately the same size (e.g., have approximately the same number of square feet of living space) while unit 12c is larger than units 12a-b and 12d and unit 12d is smaller than units 12a-c. One having ordinary skill in the art will appreciate that the building 10 may include a plurality of units 12 having only similar sizes and/or include one or more units 12 that are larger than, or smaller than, other units 12 within the building 10. Furthermore, one having ordinary skill in the art will appreciate that, in some embodiments, each unit 12 is configured with a respective plurality of interior temperature sensors 20. In alternative embodiments, each unit 12 is configured with one interior temperature sensor 20 located in a central area to that respective particular unit 12. In some embodiments, it may be advantageous to place the sensors in locations that will generate an accurate measurement of a unit's 12 air temperature, such as outside of the effects of warm appliance, sunlight and/or colder exterior walls. In some embodiments, each unit 12 is configured with a plurality of heaters 14, while in alternative embodiments each unit 12 is configured with one heater 14.

Moreover, one having ordinary skill in the art will appreciate that the environment illustrated in FIG. 2 is also not intended to limit the scope of the present disclosure. In particular, while FIG. 2 illustrates a computing system 32 and separate computing systems for the service 44, it will be appreciated that the computing system 32, or at least a portion thereof, may be incorporated into the service 44 consistent with embodiments of the invention. Moreover, although the data store 50 and the UCMA 52 are illustrated as being configured on computing system 32, it will be appreciated that the data store 50 and/or the UCMA 52 may be configured across more than one computing system consistent with embodiments of the invention. Specifically, the components of the data store 50 and/or the UCMA 52 illustrated in FIG. 3 and FIG. 4, respectively, may be configured across a plurality of computing systems without departing from the scope of the invention.

Furthermore, one having ordinary skill in the art will recognize that the environments illustrated in FIG. 3 and/or FIG. 4 for the data store 50 and/or the UCMA 52, respectively, are not intended to limit the scope of present disclosure. For example, and with respect to FIG. 3, one skilled in the art will appreciate that the data store 50 may include more or fewer tables, and that in alternative embodiments one or more of the tables of the data store 50 may be combined. Similarly, and with respect to FIG. 4, one skilled in the art will appreciate that the UCMA 52 may include more or fewer components. Indeed, those having skill in the art will recognize that other alternative hardware and/or software environments may be used without departing from the scope of the invention.

The routines executed to implement the embodiments of the invention, whether implemented as part of an operating system or a specific application, component, program, object, module or sequence of instructions executed at least in part by one or more computing systems will be referred to herein as a “sequence of operations,” a “program product,” or, more simply, “program code.” The program code typically comprises one or more instructions that are resident at various times in various memory and storage devices in a computing system, and that, when read and executed by one or more processors of the computing system, cause that computing system to perform the steps necessary to execute steps, elements, and/or blocks embodying the various aspects of the invention.

While the invention has and hereinafter will be described in the context of fully functioning computing systems, those skilled in the art will appreciate that the various embodiments of the invention are capable of being distributed as a program product in a variety of forms, and that the invention applies equally regardless of the particular type of computer readable signal bearing media used to actually carry out the distribution. Examples of computer readable signal bearing media include but are not limited to physical and tangible recordable type media such as volatile and nonvolatile memory devices, floppy and other removable disks, hard disk drives, optical disks (e.g., CD-ROM's, DVD's, etc.), among others, and transmission type media such as digital and analog communication links.

In addition, various program code described hereinafter may be identified based upon the application or software component within which it is implemented in a specific embodiment of the invention. However, it should be appreciated that any particular program nomenclature that follows is used merely for convenience, and thus the invention should not be limited to use solely in any specific application identified and/or implied by such nomenclature. Furthermore, given the typically endless number of manners in which computer programs may be organized into routines, procedures, methods, modules, objects, and the like, as well as the various manners in which program functionality may be allocated among various software layers that are resident within a typical computer (e.g., operating systems, libraries, APIs, applications, applets, etc.), it should be appreciated that the invention is not limited to the specific organization and allocation of program functionality described herein.

### Flows

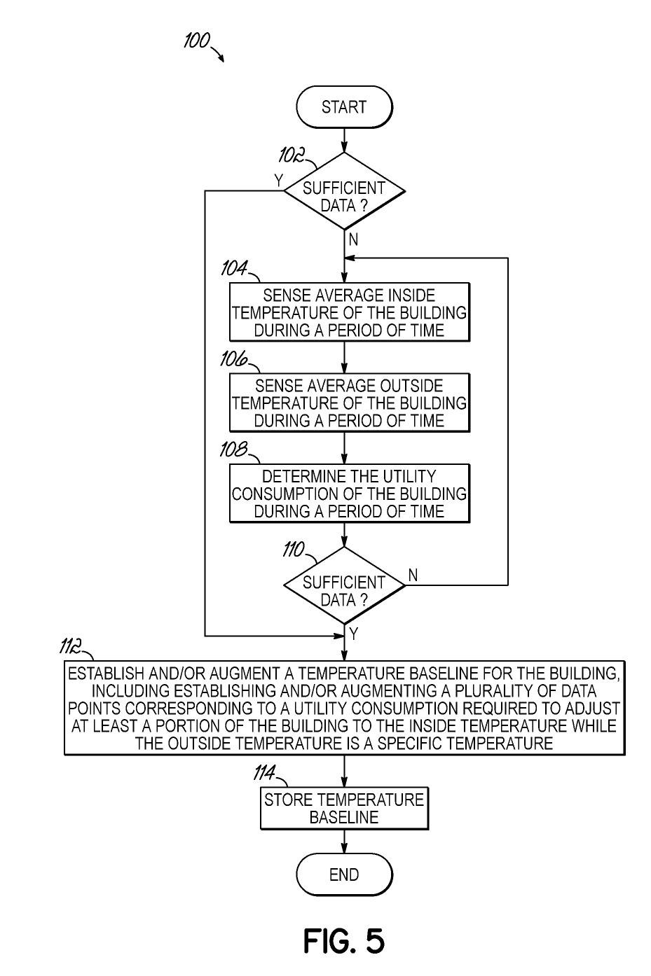

FIG. 5 is a flowchart illustrating a sequence of operations 100 that may be used to set up a calculation of utility consumption of at least one unit of a building. Specifically, at least a portion of the blocks of the flowchart may be executed by at least one computing system to set up the calculation of utility consumption. Thus, initially, it may be determined whether there is sufficient data to establish and/or augment a temperature baseline (block 102). In some embodiments, a temperature baseline is a determination of the efficiency of the building and/or at least one unit thereof. For example, the temperature baseline may indicate a relationship between the average monthly temperature of the outside of the building versus the utility consumption of that building. Alternately, and also for example, the temperature baseline may indicate the utility consumption required to adjust at least a portion of the building to a particular inside temperature in light of a specific outside temperature. However, since the building may be similar to other buildings that have been previously associated with temperature baselines (e.g., buildings with the same layout, same builder, built at the same time), there may be sufficient data to establish and/or augment a temperature baseline associated at least partially therewith (“Yes” branch of decision block 102) (e.g., a temperature baseline for a separate building, or a plurality of separate buildings, is used as the temperature baseline for the building).

When there is not sufficient data to establish and/or augment a temperature baseline for the building and/or at least one unit (“No” branch of decision block 102) an average inside temperature of the building during a predetermined period of time may be sensed (block 104). Specifically, at least one temperature sensor placed inside each unit of a building may determine a temperature, or a plurality of temperatures, during a predetermined period of time. The inside sensors may then determine an average of the temperatures, or the sensors may transmit the temperatures to a sensor reader and/or computer, which may in turn average the temperatures. Similarly, an average outside temperature during the predetermined period of time may be sensed (block 106). Moreover, the utility consumption of the building during the predetermined period of time may also be determined (block 108). In some embodiments, the utility consumption may include an indication of the electricity, gas, oil, wood, fuel pellets and/or water used during the predetermined period of time, as well as the cost thereof. As such, it may be again determined whether there is sufficient data to establish and/or augment a temperature baseline (block 110). When there is insufficient data to establish and/or augment a temperature baseline (“No” branch of decision block 110), the flowchart may return to averaging inside temperatures, averaging outside temperatures and determining utility consumption of a building during another predetermined period of time (blocks 104, 106, 108).

When there is sufficient data to establish and/or augment a temperature baseline (“Yes” branch of decision block 102 or 110), such as about ten data points indicating the average inside temperature, average outside temperature and utility consumption during about ten respective periods of time, the temperature baseline may be established and/or augmented (block 1112).

In some embodiments, establishing and/or augmenting the temperature baseline may include establishing and/or augmenting a plurality of data points corresponding to a utility consumption required to adjust at least a portion of the building to the average inside temperature in light of a specific average outside temperature. For example, the ten data points may indicate that there is an exponential relationship between the utility consumption required to adjust at least a portion of the building to a particular average inside temperature in light of a particular average outside temperature. Specifically, there may be exponentially more utility consumption required to adjust at least a portion of the building to an inside temperature when the outside temperature is further away from the inside temperature (e.g., when it is relatively cold outside as compared to the inside) in relation to when the outside temperature is relative close to the inside temperature (e.g., when it is relatively cool, comfortable or warm outside as compared to the inside). Likewise, there may be relatively little or no utility consumption required to adjust at least a portion of the building to an inside temperature when the outside temperature is the same as the inside temperature. Alternatively, the ten data points may indicate that there is a linear relationship between the utility consumption required to adjust at least a portion of the building to a particular average inside temperature in light of a particular average outside temperature.

As such, the temperature baseline may be established and/or augmented by establishing and/or interpolating a plurality of data points that indicate the utility consumption required to adjust at least a portion of the building to a specific average inside temperature in light of a specific average outside temperature based upon the collected data. Specifically, the temperature baseline may be established and/or augmented by determining best-fit data for an exponential and/or linear relationship that corresponds to the collected data. More specifically, the temperature baseline may be established and/or augmented by determining best-fit data through a spreadsheet-application, such as Microsoft Excel®, or a database application. The temperature baseline, which may include the plurality of data points, may then be stored (114).

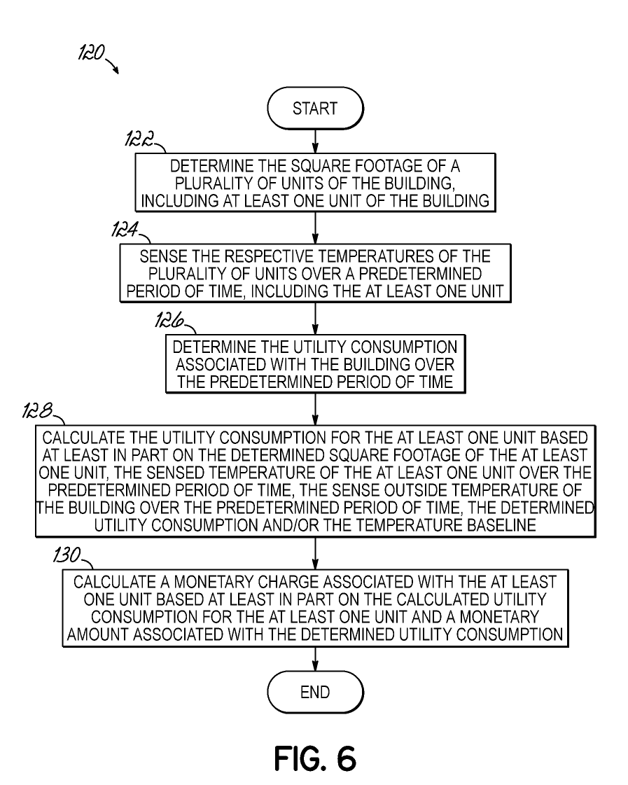

FIG. 6 is a flowchart illustrating a sequence of operations 120 that may be used to calculate the utility consumption of at least one unit of a building. Initially, the square footage of a plurality of units, including at least one unit, of the building may be determined (block 122). It will be appreciated that the square footage of the units may be determined by measurements at the units and/or through reference to plans associated with the building. The respective temperatures of the plurality of units, including the at least one unit, may then be sensed over a predetermined period of time (block 124). In some embodiments, the respective temperatures of the plurality of units are sensed by at least one respective temperature sensor configured in at least a portion of the plurality of units. Each temperature sensor may be configured to sense a plurality of temperatures over the predetermined period of time, average them, then provide that averaged temperature to a sensor reader and/or a computing system (e.g., thus providing an average inside temperature sensed by that temperature sensor for a particular unit). Alternatively, each temperature sensor may be configured to sense a plurality of temperatures over the predetermined period of time then provide those plurality of temperatures to the sensor reader and/or the computing system (e.g., thus providing a plurality of inside temperatures sensed by that temperature sensor for a particular unit to the sensor reader and/or computing system for that sensor reader and/or computing system to average to obtain the average inside temperature sensed by that temperature sensor). It will be appreciated that the same temperatures sensors used to sense the average inside temperature discussed in connection with FIG. 5 may be those used to sense the respective temperatures of the plurality of units. Moreover, the utility consumption associated with the building over the predetermined period of time may be determined (block 126).

In response to determining the square footage (block 122), sensing the temperature over the predetermined period of time (block 124) and/or determining the utility consumption over the predetermined period of time (block 126), a utility consumption for the at least one unit may be calculated (block 128). Specifically, the utility consumption for the at least one unit may be calculated based at least in part on the determined square footage of the at least one unit, the sensed temperature for the at least one unit over the predetermined period of time, the sensed average outside temperature of the building over the predetermined period of time, the determined utility consumption of the building and/or the temperature baseline associated with the building. In response to calculating the utility consumption for the at least one unit, a monetary charge associated with the as least one unit may be calculated (block 130). Specifically, the monetary charge may be a portion of the total monetary amount associated with the determined utility consumption that corresponds to the calculated utility consumption for the at least one unit (e.g., that unit's portion of the total utility bill). Thus, the monetary charge may be calculated based at least in part on the calculated utility consumption for the at least one unit and a monetary amount associated with the determined utility consumption of the building.

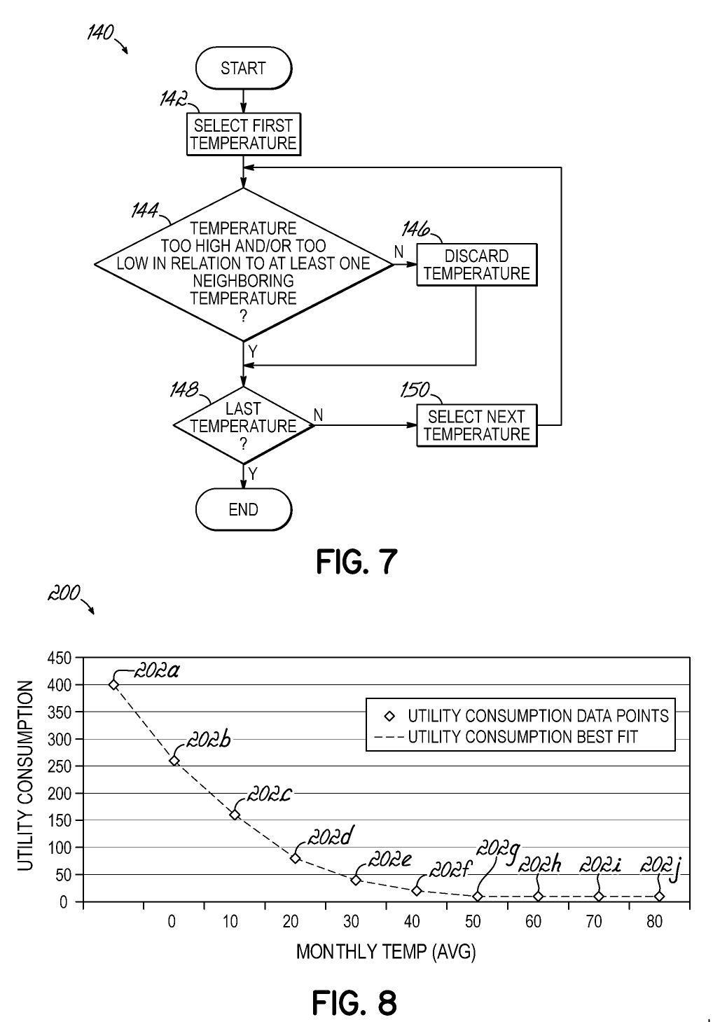

One or more of the sensed temperatures may be associated with an anomaly, such as a temporary temperature spike that may indicate a tenant is attempting to tamper with a temperature sensor. Spikes in temperature may only be a slight disruption, as the average temperature of a predetermined time may be used. FIG. 7 is a flowchart illustrating a sequence of operations 140 to discard anomalous temperature readings by a temperature sensor. Specifically, the sequence of operations 140 may be executed by a sensor reader and/or computing system that receives a plurality of temperatures from the temperature sensor. As such, the first temperature from the temperature sensor is selected (block 142) and it may be determined whether that temperature is too high and/or too low in relation to at least one neighboring temperature (block 144). For example, a temperature may be too high when it is more than about 30% above at least one neighboring temperature and/or a temperature may be too low when it is more than about 30% below at least one neighboring temperature. When the temperature is too high and/or too low in relation to the at least one neighboring temperature (“Yes” branch of decision block 144), that temperature may be discarded (block 146).

When the temperature is not too high and/or too low in relation to the at least one neighboring temperature (“No” branch of decision block 144), it may be determined whether the temperature is the last temperature (block 148). When the temperature is not the last temperature (“No” branch of decision block 148) the next temperature may be selected for analysis (block 150) and the sequence of operations 140 may return to block 144. When the temperature is the last temperature (“Yes” branch of decision block 148) the sequence of operations 140 may end. It will be appreciated by one having ordinary skill in the art that different thresholds of percentages of temperatures may be used. For example, one having ordinary skill in the art will appreciate that the 30% threshold disclosed above is merely illustrative, and that higher or lower thresholds may be used to determine anomalous temperatures.

Further details and embodiments of the present invention will be described by way of the following examples and display representations.

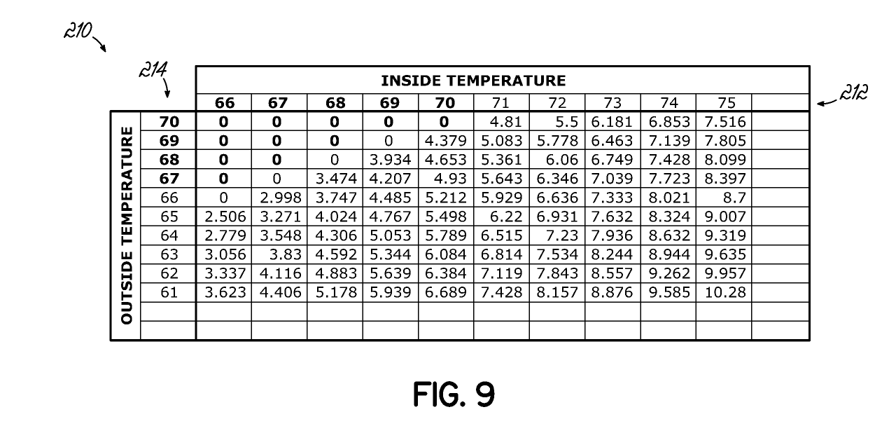

FIG. 8 is a display representation of a graph 200 that illustrates a relationship between the average utility consumption associated with a building and the average outside temperature associated with that building. Specifically, the graph 200 illustrates the relationship between a gas consumption of the building and the average outside temperature. As illustrated in FIG. 8, the graph 200 includes a plurality of data points 202a-j that indicate the utility consumption at particular average outside temperatures as well as a best fit line 204 that illustrates the general utility consumption expected at particular temperatures. In some embodiments, and as illustrated in FIG. 8, the best fit line 204 illustrates an exponential relationship for the general utility consumption expected at particular temperatures. In alternate embodiments (not shown), the best fit line 204 illustrates a linear relationship for the general utility consumption expected at particular temperatures. In specific embodiments, data points 202a-j and/or the best fit line 204 may be used to establish and/or augment a plurality of data points corresponding to a utility consumption required to adjust at least a portion of the building to the average inside temperature in light of a specific average outside temperature. Specifically, the plurality of data points may include the data points 202a-j as well as the values indicated by the best fit line 204

FIG. 9 is a display representation that diagrammatically illustrates at least a portion of a data store that may include the plurality of data points 210. Specifically, the data store may be a database or spreadsheet in which the data points 210 indicate the utility consumption required to adjust at least a portion of the building to the average inside temperature (average inside temperatures listed in the column indicated at 212) in light of a specific average outside temperature (average outside temperatures listed in the column indicated at 214). As such, the data points 210 may be used as the temperature baseline that, in turn, may be used to calculate the utility consumption for at least one unit. Specifically, an operator may enter an average inside temperature for at least one unit as well as the average outside temperature for a building associated therewith for the same predetermined period of time. When the average inside temperature for the at least one unit is 75 and the average outside temperature is 61, the plurality of data points 210 illustrated in FIG. 9 indicate that the utility consumption for the at least one unit is 10.28. As illustrated in FIG. 9, the plurality of data point 210 indicate the utility consumption of natural gas, and thus the plurality of data points 210 indicate that 10.28 cubic feet of gas is consumed to adjust the average inside temperature for the at least one unit to 75 when the average outside temperature is 61. The utility consumption of the at least one unit may then be compared to the total utility consumption of the building (e.g. the utility consumption of a plurality of units) and a tenant associated with that at least one unit may be charged accordingly. In some embodiments, and as illustrated in FIG. 9, when the average outside temperature is the same as the average outside temperature the utility consumption associated with the building is forced to zero. It will be appreciated that in alternative embodiments, the utility consumption may not be forced to zero and, may instead, include utility consumptions when the average outside temperature is the same and/or greater than the average inside temperature.

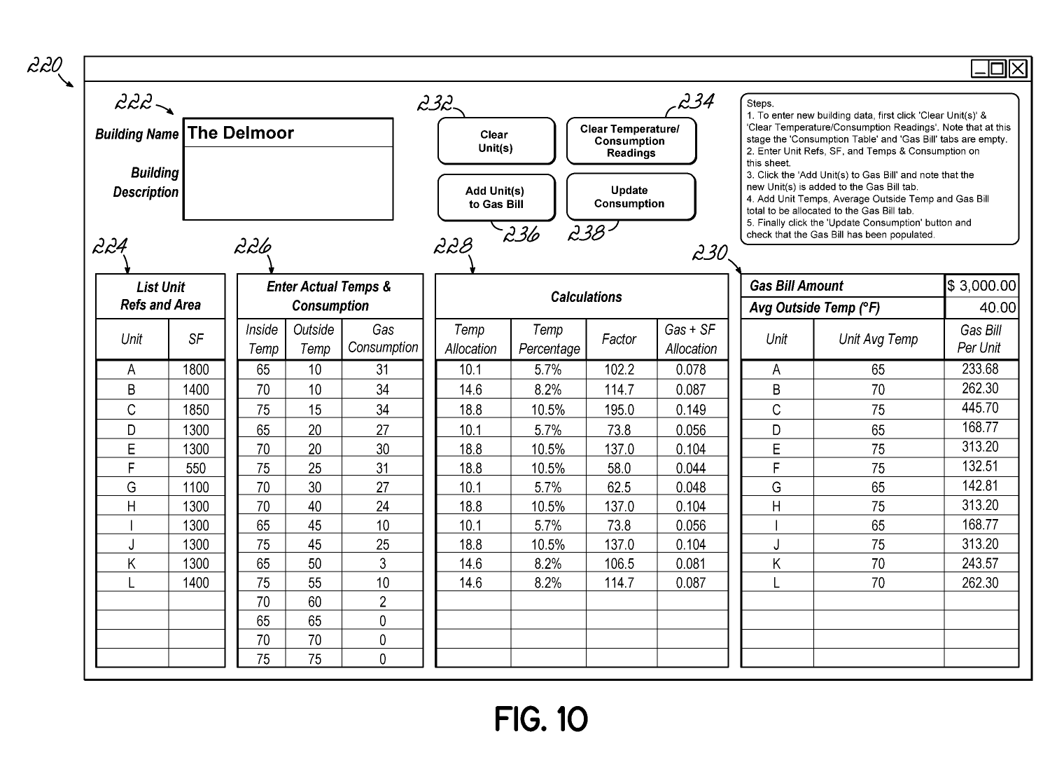

FIG. 10 is a display representation of at least a portion of a calculation and information screen 220 (hereinafter, “screen” 220) to input information related to the utility consumption of at least one unit of a building and indicate a calculation of the utility consumption associated therewith. The screen 220 illustrates information that may be entered by an operator as well as results of calculations associated with the calculation of the utility consumption of at least one unit and results of a calculation of the utility consumption of at least one unit itself. As illustrated in FIG. 10, the screen 220 may include a building information module 222, a unit information module 224, a utility consumption module 226, a calculations module 228 and a utility allocation module 230. Specifically, the screen 220 and the modules 222-230 illustrate information specific to the consumption of natural gas for heating.

In some embodiments, an operator may interact with the building information module 222 to indicate the name or title of a building as well as a description thereof. As such, information specific to a building associated with an operator may be displayed in the building information module 222. Similarly, an operator may interact with the unit information module 224 to indicate the number of units associated with a building as well as the square footage associated therewith. Although not shown, the unit information module 224 may be further configured to capture information about entities associated with a unit, such as their billing information, contact information and/or other information.

In some embodiments, a temperature baseline may be used to determine the efficiency of a building as well as the utility consumption required to adjust at least a portion of the building to a specific inside temperature in light of a particular outside temperature. As such, an operator may interact with the utility consumption module 226 to indicate the utility consumption of the building, as well as the average inside and outside temperatures associated therewith, during a predetermined period of time. In turn, the utility consumption of the building, as well as the average inside and outside temperatures associated therewith, during a predetermined period of time may be analyzed to determine the temperature baseline. Thus, a calculations module 228 may be configured to indicate at least a portion of the calculations associated with determining the allocation of a gas bill to at least one unit of the building. For example, the “Temperature Allocation” column may indicate the utility consumption required to adjust a respective unit (e.g., the unit indicated on the same row of the unit information module 24) of the building to a specific inside temperature in light of a particular outside temperature. As illustrated, the “Temperature Allocation” column indicates the calculated gas consumption required to adjust a respective unit to an average inside temperature (the average inside temperature of the respective unit is indicated in the “Unit Avg Temp” column of utility allocation module 230) in light of the average outside temperature being about 40° Fahrenheit (the average outside temperature associated with the building is indicated in the “Avg Outside Temp” row of the utility allocation module 230). It will be appreciated that the calculated utility consumption required to adjust a respective unit to a specific average inside temperature in light of a particular average outside temperature may be determined from the temperature baseline, and in particular the plurality of data points thereof. Thus, and referring to the calculations module 228, the percentage of the temperature allocation for each unit may be calculated (e.g., the calculated utility consumption required to adjust a respective unit to a specific average inside temperature in light of a particular average outside temperature divided by the total calculated utility consumption required to adjust all respective units to their respective specific average inside temperatures in light of the particular average outside temperature) and indicated in the “Temperature Percentage” column. In turn, the percentage of the temperature allocation for each unit may be multiplied by the respective square footage to determine a respective calculation factor indicated in the “Factor” column of the calculations module 228. The calculation factor for each unit may then be divided by the combined calculation factors for all units to determine a utility and square footage for each respective unit as indicated in the “Gas and Square Footage Allocation” column of the calculations module 228.

Thus, a utility bill associated with the building, and more particular a plurality of units thereof, may be allocated across the plurality of units in a manner accounting for the respective average inside temperatures and the respective square footages thereof. Specifically, the utility allocation module 230 may be configured to indicate the cost of utility consumption of a building during a predetermined period of time, the average outside temperature during a predetermined period of time, the average inside temperature of each of the plurality of units over the predetermined time, and the allocation of cost of the utility consumption per unit. The allocation of cost of the utility consumption per unit may be determined by multiplying the utility and square footage for each respective unit (e.g., as indicated in the “Gas and Square Footage Allocation” column of the calculations module 228) by the cost of utility consumption of a building during a predetermined period of time (e.g., as indicated in the “Gas Bill Amount” row of the utility allocation module 230). The respective allocation of costs may then be indicated in the utility allocation module 230 (e.g., in the “Gas Bill Per Unit” column of the utility allocation module 230).

As illustrated in FIG. 10, the screen 220 may include a plurality of display representations of buttons 232-238 to calculate the utility consumption associated with a building. Interactions with a button 232-238 may cause at least one action to occur. Specifically, interaction with a “Clear Unit(s)” button 232 may clear information about at least one unit that has previously been associated with a building, interaction with a “Clear Temperature/Consumption Readings” button 234 may clear at least one temperature (e.g., average inside and/or outside temperature) and consumption reading associated with a unit and/or building, interaction with an “Add Unit(s)” button 236 may allow a user to add at least one unit to a building and/or interaction with an “Update Consumption” button 238 may update consumption information that, in turn, is used to establish a temperature baseline for a building, and thus entering data associated with a utility consumption may update a temperature baseline associated with the building.

In addition to calculating the utility consumption of at least one unit of a building, credits may be used to incentivize changes in the utility consumption associated with the at least one unit. For example, tenants typically consume the greatest amount of utility consumption, as well as the greatest amount of costs associated therewith, in the winter. The tenants are typically charged throughout the year based on projected utility consumption costs. However, financial incentives may be provided for tenants reducing their utility consumptions. For example, by directly billing a tenant for their utility consumption the tenant may be encouraged to reduce utility consumption. The manager of a building may then raise rents by an amount and charge the tenant based on their utility consumption. If the tenant reduces utility consumption or works to remediate utility consumption, they may be provided with credits toward the next charge of utility consumption.

While the present invention has been illustrated by a description of the various embodiments and the examples, and while these embodiments have been described in considerable detail, it is not the intention of the applicants to restrict or in any way limit the scope of the appended claims to such detail. Additional advantages and modifications will readily appear to those skilled in the art. Thus, the invention in its broader aspects is therefore not limited to the specific details, representative apparatus and method, and illustrative example shown and described. In particular, it will be appreciated by one having skill in the art that different periods of time may be used than those described herein without departing from the scope of the present disclosure. For example, and in alternative embodiments, each at least one temperature sensor and/or each at least one exterior temperature sensor may be configured to determine the average temperature of its respective unit and/or average temperate associated with the outside of the building, respectively, for the period of time between which those sensors communicate their respective average temperatures. Furthermore, it will be appreciated by one having skill in the art that common areas of a building may also be monitored similarly to units of the building. Therefore, the utility consumption of common areas of a building and costs associated therewith (which may be the considered to be the responsibility of the managers of that building) may be deducted from the total utility consumption of the building and costs associated therewith. Alternatively, the utility consumption of common areas of the building and costs associated therewith may be split equitably amongst the tenants.

Moreover, any of the blocks of the above flowcharts may be deleted, augmented, made to be simultaneous with another, combined and/or otherwise altered in accordance with the principles of the present disclosure. For example, although the blocks of FIGS. 5-7 are illustrated as being in a specific order, any of the blocks of FIGS. 5-7 may be combined, made concurrent, and/or re-ordered without departing from the scope of the present disclosure. Similarly, any of the illustrative graphs, tables, data points, screens and/or modules thereof may be deleted, augmented, combined and/or otherwise altered in accordance with the principles of the present disclosure. For example, the data points illustrated in FIG. 8 are merely illustrative and not required to coincide with points on the best fit line associated therewith. Moreover, although FIG. 8 illustrates a best fit line with a substantially exponential relationship, one having ordinary skill in the art will appreciate that a best fit line with a substantially linear relationship may be used without departing from the scope of the present disclosure. Similarly, a data store may include more than that portion illustrated in FIG. 9.

Furthermore, a screen for an operator may include more or fewer calculations, information and/or interactable elements than those illustrated in FIG. 10. Additionally, it will be appreciated by one having ordinary skill in the art that the utility consumption of a utility other than natural gas may be calculated and/or displayed. For example, the utility consumption of electricity, water and/or another utility may be calculated and displayed. Moreover, it will be appreciated by one having ordinary skill in the art that a screen for an operator may include more or fewer modules than those illustrated in FIG. 10, that the modules may be presented in different orientations and/or that the screen may be presented in a different orientation without departing from the scope of the present invention. As such, FIG. 10 is not intended to limit the scope of the present disclosure. Accordingly, departures may be made from such details without departing from the spirit or scope of applicants' general present disclosure.

Other modifications will be apparent to one having ordinary skill in the art. Therefore, embodiments of the invention lie in the claims hereinafter appended.

What is claimed is:

1. A method of calculating utility consumption for at least one unit of a building having a plurality of units, comprising:
determining a square footage of the at least one unit;
sensing a temperature of the at least one unit over a predetermined period of time; and
calculating utility consumption for the at least one unit based at least in part on the determined square footage of the at least one unit and the sensed temperature of the at least one unit.

2. The method of claim 1, further comprising:
determining the utility consumption associated with the building over the predetermined period of time, wherein calculating the utility consumption for the at least one unit is further based at least in part on the determined utility consumption.

3. The method of claim 1, further comprising:
establishing a temperature baseline for the at least one unit over the predetermined period of time, wherein calculating the utility consumption for the at least one unit is further based at least in part on the established temperature baseline.

4. The method of claim 1, further comprising:
determining the utility consumption associated with the building over the predetermined period of time; and
calculating a monetary charge associated with the at least one unit based at least in part on the calculated utility consumption and the determined utility consumption.

5. The method of claim 4, wherein calculating the monetary charge includes:
determining a monetary amount associated with the determined utility consumption; and
determining a percentage of the monetary amount associated with the calculated utility consumption.

6. The method of claim 1, further comprising:
sensing a plurality of inside temperatures associated with the building over a respective plurality of periods of time;
sensing a plurality of outside temperatures associated with the building over the respective plurality of periods of time;
determining a plurality of utility consumptions of the building over the respective plurality of periods of time; and
establishing a plurality of data points corresponding to a utility consumption required to adjust at least a portion of the building to the inside temperature.

7. The method of claim 6, wherein the plurality of data points are associated with an efficiency of the building.

8. The method of claim 6, wherein each period of time is about a six-hour period of time.

9. The method of claim 6, wherein each inside temperature is an average temperature for that respective period of time.

10. The method of claim 6, wherein each outside temperature is an average temperature for that respective period of time.

11. The method of claim 6, wherein calculating the utility consumption for the at least one unit is further based at least in part on the plurality of data points.

12. The method of claim 6, wherein establishing the plurality of data points includes interpolating at least a portion of the plurality of data points, and wherein calculating the utility consumption for the at least one unit is further based at least in part on at least a portion of the interpolated data points.

13. The method of claim 1, further comprising:
placing at least one temperature sensor in each of the plurality of units.

14. An system, comprising:
at least one processing unit; and
a memory including program code, the program code configured to be executed by the at least one processing unit to calculate utility consumption for at least one unit of a building of the type that includes a plurality of units by determining a square footage of the at least one unit, sensing a temperature of the at least one unit over a predetermined period of time and calculating the utility consumption for the at least one unit based at least in part on the determined square footage of the at least one unit and the sense temperature of the at least one unit.

15. The system of claim 14, wherein the program code is further configured to determine the utility consumption associated with the building over the predetermined period of time and wherein calculating the utility consumption for the at least one unit is further based at least in part on the determined utility consumption.

16. The system of claim 14, wherein the program code is further configured to establish a temperature baseline for the at least one unit over the predetermined period of time and wherein calculating the utility consumption for the at least one unit is further based at least in part on the established temperature baseline.

17. The system of claim 14, wherein the program code is further configured to determine the utility consumption associated with the building over the predetermined period of time and calculate a monetary charge associated with the at least one unit based at east in part to the calculated utility consumption and the determined utility consumption.

18. The system of claim 17, wherein the program code is further configured to determine a monetary amount associated with the determined utility consumption and determine a percentage of the monetary amount associated with the calculated utility consumption.

19. The system of claim 14, wherein the program code is further configured to sense a plurality of inside temperatures associated with the building over a respective plurality of periods of time, sense a plurality of outside temperatures associated with the building over the respective plurality of periods of time, determine a plurality of utility consumptions of the building over the respective plurality of periods of time and establish a plurality of data points corresponding to a utility consumption required to adjust at least a portion of the building to the inside temperature.

20. The system of claim 19, wherein the plurality of data points are associated with an efficiency of the building.

21. The system of claim 19, wherein the program code is further configured to calculate the utility consumption for the at least one unit based at least in part on the plurality of data points.

22. The system of claim 19, wherein the program code is further configured to interpolate at least a portion of the plurality of data points to establish the plurality of data points and wherein calculating the utility consumption for the at least one unit is further based at least in part on at least a portion of the interpolated data points.

23. A program product, comprising:
program code configured to calculate utility consumption for at least one unit of a building of the type that includes a plurality of units by determining a square footage of the at least one unit, sensing a temperature of the at least one unit over a predetermined period of time and calculating the utility consumption for the at least one unit based at least in part on the determined square footage of the at least one unit and the sense temperature of the at least one unit; and
a recordable tape media bearing the program code.
